(19) United States
(12) Patent Application Publication
(10) Pub. No.: US 2024/0392048 A1
(43) Pub. Date: Nov. 28, 2024

(54) POLYMER, PHOTOSENSITIVE RESIN COMPOSITION, PHOTOSENSITIVE ELEMENT, METHOD FOR FORMING RESIST PATTERN, AND METHOD FOR FORMING WIRING PATTERN

(71) Applicants: Resonac Corporation, Tokyo (JP); SHANGHAI JIAO TONG UNIVERSITY, Shanghai (CN)

(72) Inventors: Hiroshi MATSUTANI, Tokyo (JP); Bao LI, Tokyo (JP); Yasuharu MURAKAMI, Tokyo (JP); Masato MIYATAKE, Tokyo (JP); Akitoshi TANIMOTO, Tokyo (JP); Xuesong JIANG, Shanghai (CN); Xiao-dong MA, Shanghai (CN)

(21) Appl. No.: 18/695,159

(22) PCT Filed: Sep. 28, 2021
(86) PCT No.: PCT/CN2021/121321

§ 371 Date: Mar. 25, 2024

(51) Int. Cl. C08F 212/08; G03F 7/031; G03F 7/105; G03F 7/34

(52) U.S. Cl. CPC C08F 212/08; G03F 7/031; G03F 7/105; G03F 7/34

(57) ABSTRACT

An aspect of the present disclosure relates to a polymer including a structural unit represented by the following Formula (I) and a structural unit having a carboxy group. In Formula (I), R¹ represents a hydrogen atom or a methyl group; M represents an alkylene group or an alkylene oxide chain; and R² represents an alkyl group or an aryl group.

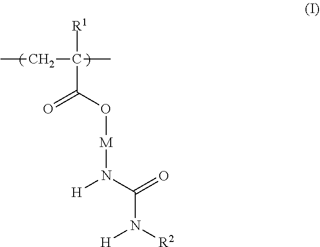

### TECHNICAL FIELD

The present disclosure relates to a polymer, a photosensitive resin composition, a photosensitive element, a method for forming a resist pattern, and a method for forming a wiring pattern.

### BACKGROUND ART

In the field of manufacturing of printed wiring boards, photosensitive resin compositions and photosensitive elements (laminated bodies) comprising a layer (hereinafter, also referred to as “photosensitive layer”) formed by using a photosensitive resin composition on a support film have been widely used as resist materials that are used for an etching treatment, a plating treatment, or the like.

Printed wiring boards are manufactured by, for example, the following procedure by using the above-described photosensitive elements. That is, first, a photosensitive layer of a photosensitive element is laminated on a circuit forming substrate such as a copper clad laminated plate. Next, the photosensitive layer is exposed to light through a mask film or the like to form a photocured part. At this time, the support film is peeled off before exposure or after exposure. Thereafter, regions other than the photocured part in the photosensitive layer are removed with a developer liquid to form a resist pattern. Next, the resist pattern is used as a resist, an etching treatment or a plating treatment is applied thereto to form a conductor pattern, and finally the photocured part (resist pattern) of the photosensitive layer is peeled off (removed).

A photosensitive resin composition is required to be able to form a resist pattern having excellent resolution and to exhibit excellent peeling characteristics of the resist pattern (see, for example, Patent Literatures 1 and 2).

### CITATION LIST

### Patent Literature

Patent Literature 1: JP 2005-122123 A
Patent Literature 2: JP 2006-234995 A

### SUMMARY OF INVENTION

### Technical Problem

A photosensitive resin composition is not only required to form a resist pattern having excellent resolution and peeling characteristics, but also required to have excellent conformability for a circuit forming substrate when a photosensitive layer is laminated on a circuit forming substrate. It is an object of the present disclosure to provide a novel polymer that is used for a photosensitive resin composition having excellent conformability during lamination, a photosensitive resin composition, a photosensitive element, a method for forming a resist pattern, and a method for forming a wiring pattern.

### Solution to Problem

An aspect of the present disclosure relates to a polymer including a structural unit represented by the following Formula (I) and a structural unit having a carboxy group. In Formula (1), R¹ represents a hydrogen atom or a methyl group; M represents an alkylene group or an alkylene oxide chain; and R² represents an alkyl group or an aryl group.

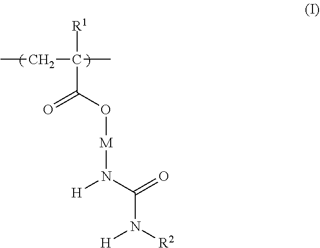

Another aspect of the present disclosure relates to a photosensitive resin composition containing a binder resin including the above-described polymer; a photopolymerizable compound; and a photopolymerization initiator.

Still another aspect of the present disclosure relates to a photosensitive element comprising a support and a photosensitive layer formed on the support, the photosensitive layer including the above-described photosensitive resin composition.

Still another aspect of the present disclosure also relates to a method for forming a resist pattern, the method comprising: a step of forming a photosensitive layer using the photosensitive resin composition or the photosensitive element; a step of irradiating at least a portion of the photosensitive layer with actinic light to form a photocured part; and a step of removing at least a portion of areas other than the photocured part in the photosensitive layer from the substrate.

Still another aspect of the present disclosure relates to a method for forming a wiring pattern, the method comprising a step of subjecting a substrate having a resist pattern formed thereon by the method for forming a resist pattern, to an etching treatment or a plating treatment to form a conductor pattern.

### Advantageous Effects of Invention

According to the present disclosure, a novel polymer that is used for a photosensitive resin composition having excellent conformability during lamination, a photosensitive resin composition, a photosensitive element, a method for forming a resist pattern, and a method for forming a wiring pattern can be provided.

### BRIEF DESCRIPTION OF DRAWINGS

FIG. 1 is a schematic cross-sectional view illustrating an embodiment of a photosensitive element.

FIG. 2 is an electron microscopic photograph of a resist pattern formed in Example 5.

FIG. 3 is an electron microscopic photograph of a resist pattern formed in Comparative Example 2.

### DESCRIPTION OF EMBODIMENTS

Hereinafter, embodiments of the present disclosure will be described in detail. However, the present disclosure is not intended to be limited to the following embodiments.

In the present description, the term “step” includes not only an independent step but also a step that cannot be clearly distinguished from other steps, as long as the predetermined action of the step is achieved. The numerical value range shown using “to” shows the range which includes the numerical values described before and after “to” as the minimum value and the maximum value, respectively. The term “layer” includes not only a structure of a shape formed on the entire surface but also a structure of a shape formed in part when it is observed as a plan view. “(Meth)acrylic acid” means at least one of “acrylic acid” or “methacrylic acid” corresponding thereto. The same applies to other similar expressions such as (meth)acrylate and (meth)acryloyl.

In the present description, when a plurality of substances corresponding to each component are present, unless otherwise specified, the amount of each component in the photosensitive resin composition means the total amount of the plurality of substances present in the photosensitive resin composition. In the numerical value ranges described in the present description, the upper limit value or the lower limit value of the numerical value range may be replaced with the values shown in Examples. Moreover, an embodiment which arbitrarily combines the matters described in this description is also included in the present invention. In the present description, the term “solid content” refers to a non-volatile fraction excluding volatile substances such as water and solvents included in the photosensitive resin composition. That is, the “solid content” refers to components other than the solvents that remain without volatilizing during drying of the photosensitive resin composition as will be described below, and the solid content also includes components in a liquid form, a starch syrup form, and a wax form at room temperature (25° C.).

### [Polymer]

The polymer according to the present embodiment includes a structural unit represented by the following Formula (I) and a structural unit having a carboxy group.

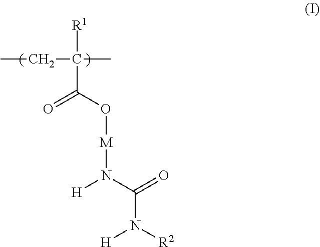

In Formula (I), R¹ represents a hydrogen atom or a methyl group; M represents an alkylene group or an alkylene oxide chain; and R² represents an alkyl group or an aryl group.

The number of carbon atoms of the alkylene group may be 1 to 6, 1 to 4, or 1 to 3. With regard to the alkylene oxide chain, the number of repetitions of the alkylene oxide may be 1 to 10, 1 to 8, or 1 to 6, and the number of carbon atoms of the alkylene oxide may be 2 to 10, 2 to 6, or 2 to 4. M may be a methylene group, an ethylene group, a propylene group, a butylene group, an ethylene oxide chain, or a propylene oxide chain.

The number of carbon atoms of the alkyl group may be 1 to 20, 2 to 10, or 3 to 6. The number of carbon atoms of the aryl group may be 6 to 20, 6 to 15, or 6 to 10. R² may be a methyl group, an ethyl group, a propyl group, a butyl group, a pentyl group, a hexyl group, a heptyl group, an octyl group, a nonyl group, a decyl group, or a phenyl group.

Regarding the monomer that gives a structural unit represented by Formula (I), a reaction product of a (meth)acrylate compound having an isocyanate group and an amine compound. Examples of the (meth)acrylate compound having an isocyanate group include isocyanatomethyl (meth)acrylate, 2-isocyanatoethyl (meth)acrylate, 3-isocyanatopropyl (meth)acrylate, 2-isocyanatopropyl (meth)acrylate, 2-isocyanato-1-methylethyl (meth)acrylate, 2-isocyanatobutyl (meth)acrylate, and 2-(2-(meth)acryloyloxyethyloxy) ethylisocyanate. Examples of the amine compound include ethylamine, propylamine, butylamine, pentylamine, hexylamine, 2-methoxyethylamine, 3-methoxyethylamine, and aniline.

The polymer according to the present embodiment includes a structural unit represented by Formula (I), and when the polymer is used as a photosensitive resin composition, the conformability during lamination can be enhanced. The inventors of the present invention speculate that such an effect arises because since the polymer has a urea bond and a carboxy group in a side chain, there occurs an interaction between urea bonds, or an interaction caused by a hydrogen bond between a urea bond and a carboxy group.

The content of the structural unit represented by Formula (I) in the polymer is preferably 5% to 50% by mass based on the total amount of the polymer. The content of the structural unit represented by Formula (I) may be 6% by mass or more, 7% by mass or more, or 8% by mass or more, from the viewpoint of further enhancing the conformability. The content of the structural unit represented by Formula (I) may be 45% by mass or less, 40% by mass or less, or 35% by mass or less, from the viewpoint of enhancing the solubility of the polymer in an alkaline aqueous solution.

The polymer according to the present embodiment includes a structural unit having a carboxy group from the viewpoint of alkali developability. The content of the structural unit having a carboxy group may be 10% to 45% by mass, 15% to 40% by mass, or 20% to 35% by mass, based on the total amount of the polymer from the viewpoint of enhancing the alkali developability and alkali resistance in a well-balanced manner. When the content of the structural unit having a carboxy group is 10% by mass or more, the alkali developability tends to increase, and when the content is 45% by mass or less, the alkali resistance tends to be excellent.

Examples of the monomer that gives a structural unit having a carboxy group include (meth)acrylic acid, α-bromoacrylic acid, α-chloroacrylic acid, β-furyl (meth)acrylic acid, β-styryl (meth)acrylic acid, maleic acid; maleic acid monoesters such as maleic anhydride, monomethyl maleate, monoethyl maleate, and monoisopropyl maleate; fumaric acid, cinnamic acid, α-cyanocinnamic acid, itaconic acid, crotonic acid, and propiolic acid. It is preferable that the polymer according to the embodiment includes a structural unit based on (meth)acrylic acid, from the viewpoint of further enhancing the alkali developability.

The polymer according to the present embodiment may have a structural unit based on styrene or a styrene derivative, from the viewpoints of adhesiveness and peeling characteristics. A styrene derivative is a polymerizable compound in which the α-position of styrene or a hydrogen atom in an aromatic ring is substituted. Examples of the styrene derivative include vinyltoluene, α-methylstyrene, p-methylstyrene, and p-ethylstyrene.

The content of the structural unit based on styrene or a styrene derivative in the polymer may be 10% to 60% by mass, 15% to 55% by mass, or 25% to 50% by mass, based on the total amount of the polymer. When the content of the structural unit based on styrene or a styrene derivative is 10% by mass or more, adhesiveness tends to be enhanced, and when the content is 60% by mass or less, the peeled fragment can be suppressed from being enlarged during developing, while lengthening of the time required for peeling tends to be suppressed.

The polymer according to the present embodiment may have a structural unit based on benzyl (meth)acrylate or a benzyl (meth)acrylate derivative, from the viewpoints of resolution and the aspect ratio. Examples of the benzyl (meth)acrylate derivative include 4-methylbenzyl (meth)acrylate. The content of the structural unit based on benzyl (meth)acrylate or the benzyl (meth)acrylate derivative in the polymer may be 5% to 40% by mass, 10% to 40% by mass, or 15% to 30% by mass, based on the total amount of the polymer, from the viewpoint of enhancing resolution.

The polymer according to the present embodiment may have a structural unit based on a (meth)acrylic acid alkyl ester, from the viewpoint of enhancing plasticity. Examples of the (meth)acrylic acid alkyl ester include (meth)acrylic acid methyl ester, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

From the viewpoint of enhancing resolution, the weight average molecular weight (Mw) of the polymer may be 5000 or more, 6000 or more, 7000 or more, or 8000 or more. From the viewpoint that developing can be suitably performed, the Mw of the polymer may be 30000 or less, 28000 or less, 26000 or less, or 24000 or less. The Mw can be measured by gel permeation chromatography (GPC) using a calibration curve of polystyrene standards.

### [Photosensitive Resin Composition]

The photosensitive resin composition according to the present embodiment contains (A) a binder resin (hereinafter, may be referred to as “component (A)”); (B) a photopolymerizable compound (hereinafter may be referred to as “component (B)”); and (C) a photopolymerization initiator (hereinafter, may be referred to as “component (C)”). Each of the components which the photosensitive resin composition can contain will be explained in detail below.

### (Binder Resin)

The binder resin as component (A) includes a polymer having the above-mentioned specific structure (hereinafter, “may be referred to as component (A1)”). By using the component (A1), the conformability during lamination of the photosensitive resin composition (photosensitive layer) can be enhanced. The component (A1) may be composed only of one kind of resin or may be configured to include two or more kinds of resins.

The component (A) may further include a resin other than component (A1). Such a resin may be an alkali-soluble resin having a phenolic hydroxyl group. Examples of the resin having a phenolic hydroxyl group include hydroxystyrene-based resins such as polyhydroxystyrene and a copolymer including hydroxystyrene as a monomer unit; a phenol resin, a polybenzoxazole precursor such as poly(hydroxyamide), poly(hydroxyphenylene) ether, and polynaphthol.

The content of the component (A) may be 30 to 90 parts by mass, 40 to 85 parts by mass, or 50 to 80 parts by mass, with respect to 100 parts by mass of the total amount of the component (A) and the component (B). When the content of the component (A) is in this range, strength of the photocured part of the photosensitive layer is further improved.

### (Photopolymerizable Compound)

The photopolymerizable compound as component (B) is a compound having, for example, a functional group having an ethylenically unsaturated bond, such as a vinyl group, an allyl group, a propargyl group, a butenyl group, an ethynyl group, a phenylethynyl group, a maleimide group, a nadimide group, or a (meth)acryloyl group, as a functional group exhibiting photopolymerizability. The component (B) is not particularly limited as long as it is a compound having one or more ethylenically unsaturated groups. The functional group exhibiting photopolymerizability is preferably a (meth)acryloyl group. The component (B) may be used singly or in combination of two or more kinds thereof.

Examples of a photopolymerizable compound having one ethylenically unsaturated group include (meth)acrylic acid, a (meth)acrylic acid alkyl ester, and a phthalic acid-based compound.

Examples of the (meth)acrylic acid alkyl ester include (meth)acrylic acid methyl ester, (meth)acrylic acid ethyl ester, (meth)acrylic acid butyl ester, (meth)acrylic acid 2-ethylhexyl ester, and (meth)acrylic acid hydroxyethyl ester.

From the viewpoint of suitably enhancing the resolution, adhesiveness, and resist shape, the component (B) may include a phthalic acid-based compound. Examples of the phthalic acid-based compound include γ-chloro-β-hydroxypropyl-β′-(meth)acryloyloxyethyl-o-phthalate (also known as: 3-chloro-2-hydroxypropyl-2-(meth)acryloyloxyethyl phthalate), β-hydroxyethyl-β′-(meth)acryloyloxyethyl-o-phthalate, and β-hydroxypropyl-β′-(meth)acryloyloxyethyl-o-phthalate.

Examples of a photopolymerizable compound having two ethylenically unsaturated groups include polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, bisphenol A diglycidyl ether di(meth)acrylate, and alkylene oxide-modified bisphenol A di(meth)acrylate.

From the viewpoint of enhancing alkali developability and resolution, the component (B) may include alkylene oxide-modified bisphenol A di(meth)acrylate. Examples of the alkylene oxide-modified bisphenol A di(meth)acrylate include 2,2-bis(4-((meth)acryloxypolyethoxy)phenyl)propane (2,2-bis(4-((meth)acryloxypentaethoxy)phenyl)propane or the like), 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane.

Examples of a photopolymerizable compound having three or more ethylenically unsaturated groups include a (meth)acrylate having a skeleton derived from trimethylolpropane, such as trimethylolpropane tri(meth)acrylate; a (meth)acrylate having a skeleton derived from tetramethylolmethane, such as tetramethylolmethane tri(meth)acrylate or tetramethylolmethane tetra(meth)acrylate; a (meth)acrylate having a skeleton derived from pentaerythritol, such as pentaerythritol tri(meth)acrylate or pentaerythritol tetra(meth)acrylate; a (meth)acrylate having a skeleton derived from dipentaerythritol, such as dipentaerythritol penta(meth)acrylate or dipentaerythritol hexa(meth)acrylate; a (meth)acrylate having a skeleton derived from ditrimethylolpropane, such as ditrimethylolpropane tetra(meth)acrylate; and a (meth)acrylate having a skeleton derived from diglycerin. Among these, from the viewpoint of enhancing the chemical resistance after curing (exposure) and increasing the difference in the resistance to developer liquid between an exposed part and an unexposed part, a (meth)acrylate compound having a skeleton derived from dipentaerythritol is preferred, and dipentaerythritol penta(meth)acrylate is more preferred.

From the viewpoint of enhancing the alkali developability of an unexposed part of the photosensitive resin composition and enhancing the adhesive strength of an exposed part, the component (B) may include a photopolymerizable compound having an ethylenically unsaturated group and an acid-modified group. Examples of the acidic group to be modified include a carboxy group, a sulfo group, and a phenolic hydroxyl group, and among these, a carboxy group is preferred.

Examples of the photopolymerizable compound having an ethylenically unsaturated group and an acidic group include a styrene-maleic acid-based resin and an acid-modified epoxy derivative containing a vinyl group.

A styrene-maleic acid-based resin is a hydroxyethyl (meth)acrylate-modified product of a styrene-maleic anhydride copolymer. An acid-modified epoxy derivative containing a vinyl group is a compound obtained by reacting a compound obtained by modifying an epoxy resin with a vinyl group-containing organic acid, with a saturated group-containing or unsaturated group-containing polybasic acid anhydride.

The epoxy resin is not particularly limited as long as it is a compound having two or more epoxy groups. Examples of the epoxy resin include a glycidyl ether type epoxy resin, a glycidylamine type epoxy resin, and a glycidyl ester type epoxy resin. Among these, from the viewpoint of reliability upon semiconductor chip packaging, a bisphenol novolac type epoxy resin is preferred, and a bisphenol F novolac type epoxy resin is more preferred.

The vinyl group-containing organic acid is not particularly limited and may be a vinyl group-containing monocarboxylic acid. Examples of the vinyl group-containing monocarboxylic acid include acrylic acid derivatives such as acrylic acid, a dimer of acrylic acid, methacrylic acid, β-furfuryl acrylic acid, β-styryl acrylic acid, cinnamic acid, crotonic acid, and α-cyanocinnamic acid; a half ester compound which is a reaction product of a hydroxyl group-containing acrylate and a dibasic acid anhydride; and a half ester compound which is a reaction product of a vinyl group-containing monoglycidyl ether or a vinyl group-containing monoglycidyl ester with a dibasic acid anhydride.

Examples of a photopolymerizable compound having an α,β-unsaturated carbonyl group include an α,β-unsaturated carboxylic acid ester of a polyhydric alcohol, a bisphenol type (meth)acrylate, an α,β-unsaturated carboxylic acid adduct of a glycidyl group-containing compound, a (meth)acrylate having a urethane bond, nonylphenoxypolyethyleneoxyacrylate, and a (meth)acrylic acid alkyl ester.

Examples of the α,β-unsaturated carboxylic acid ester of a polyhydric alcohol include a polyethylene glycol di(meth)acrylate in which the number of ethylene groups is 2 to 14, a polypropylene glycol di(meth)acrylate in which the number of propylene groups is 2 to 14, a polyethylene-polypropylene glycol di(meth)acrylate in which the number of ethylene groups is 2 to 14 and the number of propylene groups is 2 to 14, trimethylolpropane di(meth)acrylate, trimethylolpropane tri(meth)acrylate, an EO-modified trimethylolpropane tri(meth)acrylate, a PO-modified trimethylolpropane tri(meth)acrylate, an EO- and PO-modified trimethylolpropane tri(meth)acrylate, tetramethylolmethane tri(meth)acrylate, tetramethylolmethane tetra(meth)acrylate, and a (meth)acrylate compound having a skeleton derived from dipentaerythritol or pentaerythritol. The term “EO-modified” means having a block structure of ethylene oxide (EO) groups, and the term “PO-modified” means having a block structure of propylene oxide (PO) groups.

From the viewpoint of enhancing the flexibility of the resist pattern, the component (B) may include a polyalkylene glycol di(meth)acrylate. The polyalkylene glycol di(meth)acrylate may have at least one of an EO group and a PO group or may have both an EO group and a PO group. With regard to the polyalkylene glycol di(meth)acrylate having both an EO group and a PO group, the EO groups and PO groups may be respectively present continuously in a block form or may be present in a random manner. Furthermore, the PO group may be either an oxy-n-propylene group or an oxyisopropylene group. In a (poly)oxyisopropylene group, a secondary carbon of the propylene group may be bonded to an oxygen atom, or a primary carbon may be bonded to an oxygen atom.

Examples of a commercially available product of the polyalkylene glycol di(meth)acrylate include FA-023M (manufactured by Showa Denko Materials Co., Ltd.), FA-024M (manufactured by Showa Denko Materials Co., Ltd.), and NK ESTER HEMA-9P (manufactured by SHIN-NAKAMURA CHEMICAL Co., Ltd.).

The component (B) may include a (meth)acrylate having a urethane bond, from the viewpoint of enhancing the flexibility of the resist pattern. Examples of the (meth)acrylate having a urethane bond include an addition reaction product of a (meth)acrylic monomer having an OH group at the β-position and a diisocyanate (isophorone diisocyanate, 2,6-toluene diisocyanate, 2,4-toluene diisocyanate, 1,6-hexamethylene diisocyanate, or the like), tris((meth)acryloxytetraethylene glycol isocyanate) hexamethylene isocyanurate, an EO-modified urethane di(meth)acrylate, and an EO- and PO-modified urethane di(meth)acrylate.

Examples of a commercially available product of the EO-modified urethane di(meth)acrylate include “UA-11” and “UA-21EB” (manufactured by SHIN-NAKAMURA CHEMICAL Co., Ltd.). Examples of a commercially available product of the EO- and PO-modified urethane di(meth)acrylate include “UA-13” (manufactured by SHIN-NAKAMURA CHEMICAL Co., Ltd.).

From the viewpoint that a resist pattern having a large thickness is easily formed and the resolution and adhesiveness are enhanced in a well-balanced manner, the component (B) may include a (meth)acrylate compound having a skeleton derived from dipentaerythritol or pentaerythritol. It is preferable that the (meth)acrylate compound having a skeleton derived from dipentaerythritol or pentaerythritol has four or more (meth)acryloyl groups, and the (meth)acrylate compound may be dipentaerythritol penta(meth)acrylate or dipentaerythritol hexa(meth)acrylate.

From the viewpoint of further enhancing the resolution and the peeling characteristics after curing, the component (B) may include a bisphenol type (meth)acrylate, and among bisphenol type (meth)acrylates, the component (B) may include a bisphenol A type (meth)acrylate. Examples of the bisphenol A type (meth)acrylate include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane. Among them, from the viewpoint of further enhancing the resolution and pattern forming properties, 2,2-bis(4-((meth)acryloxypolyethoxy)phenyl)propane is preferred.

Examples of commercially available products include BPE-200 (SHIN-NAKAMURA CHEMICAL Co., Ltd.) for 2,2-bis(4-((meth)acryloxydipropoxy)phenyl)propane, and BPE-500 (SHIN-NAKAMURA CHEMICAL Co., Ltd.) and FA-321M (Showa Denko Materials Co., Ltd.) for 2,2-bis(4-(methacryloxypentaethoxy)phenyl)propane.

Examples of nonylphenoxypolyethyleneoxyacrylate include nonylphenoxytetraethyleneoxyacrylate, nonylphenoxypentaethyleneoxyacrylate, nonylphenoxyhexaethyleneoxyacrylate, nonylphenoxyheptaethyleneoxyacrylate, nonylphenoxyoctaethyleneoxyacrylate, nonylphenoxynonaethyleneoxyacrylate, nonylphenoxydecaethyleneoxyacrylate, and nonylphenoxyundecaethyleneoxyacrylate.

### (Photopolymerization Initiator)

The photopolymerization initiator, which is component (C), is not particularly limited as long as it is a component capable of polymerizing the component (B) and can be appropriately selected from commonly used photopolymerization initiators. The component (C) can be used singly or in combination of two or more kinds thereof.

Examples of the component (C) include acylphosphine oxide-based, oxime ester-based, aromatic ketone-based, quinone-based, alkylphenone-based, imidazole-based, acridine-based, phenylglycine-based, and coumarin-based photopolymerization initiators.

From the viewpoint of enhancing sensitivity and resolution in a well-balanced manner, a hexaarylbiimidazole compound, an acridine compound, or an imidazole compound may be used as the component (C).

Examples of the hexaarylbiimidazole compound include 2-(o-chlorophenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, and 2,2′-bis-(2,5-difluorophenyl)-4,4′,5,5′-tetrakis-(3-methoxyphenyl)-biimidazole. Among them, from the viewpoints of sensitivity and adhesiveness, 2-(o-chlorophenyl)-4,5-diphenylimidazole dimer is preferred. As the 2-(o-chlorophenyl)-4,5-diphenylimidazole dimer, 2,2′-bis(2-chlorophenyl)-4,4′,5,5′-tetraphenyl-1,2-biimidazole is commercially available under trade name “B-CIM” manufactured by Hodogaya Chemical Co., Ltd.

Examples of the acridine compound include 9-phenylacridine, 9-(p-methylphenyl)acridine, 9-(m-methylphenyl)acridine, 9-(p-chlorophenyl)acridine, 9-(m-chlorophenyl)acridine, 9-aminoacridine, 9-dimethylaminoacridine, 9-diethylaminoacridine, 9-pentylaminoacridine, 1,2-bis(9-acridinyl)ethane, 1,4-bis(9-acridinyl)butane, 1,6-bis(9-acridinyl)hexane, 1,8-bis(9-acridinyl)octane, 1,10-bis(9-acridinyl)decane, 1,12-bis(9-acridinyl)dodecane, 1,14-bis(9-acridinyl)tetradecane, 1,16-bis(9-acridinyl)hexadecane, 1,18-bis(9-acridinyl)octadecane, 1,20-bis(9-acridinyl)eicosane, 1,3-bis(9-acridinyl)-2-oxapropane, 1,3-bis(9-acridinyl)-2-thiapropane, and 1,5-bis(9-acridinyl)-3-thiapentane.

Examples of the imidazole compound include 2-(o-chlorophenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, and 2,2′-bis-(2,5-difluorophenyl)-4,4′,5,5′-tetrakis-(3-methoxyphenyl)-biimidazole.

The content of the component (C) may be 0.1 to 10 parts by mass, 0.2 to 5 parts by mass, or 0.5 to 4 parts by mass, with respect to 100 parts by mass of the total amount of the component (A) and the component (B). When the content of the component (C) is 0.1 parts by mass or more, photosensitivity, resolution, and adhesiveness tend to be enhanced, and when the content is 10 parts by mass or less, the resist pattern forming properties tend to be superior.

### (Sensitizer)

The photosensitive resin composition according to the present embodiment may further contain a sensitizer as component (D). As the photosensitive resin composition contains the component (D), when exposed to light having a peak within a specific wavelength range, the photosensitive resin composition can have maximum absorption in the vicinity of the specific wavelength range, and the sensitivity of the photosensitive resin composition can be increased. The component (D) can be used singly or in combination of two or more kinds thereof.

Examples of the component (D) include a dialkylaminobenzophenone compound, a pyrazoline compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compound, a thiophene compound, a naphthalimide compound, a triarylamine compound, and an aminoacridine compound. The component (D) may include a pyrazoline compound or an anthracene compound, from the viewpoint of further enhancing the resolution.

Examples of the pyrazoline compound include 1-(4-methoxyphenyl)-3-styryl-5-phenyl-pyrazoline, 1-phenyl-3-(4-methoxystyryl)-5-(4-methoxyphenyl)-pyrazoline, 1,5-bis-(4-methoxyphenyl)-3-(4-methoxystyryl)-pyrazoline, 1-(4-isopropylphenyl)-3-styryl-5-phenyl-pyrazoline, 1-phenyl-3-(4-isopropylstyryl)-5-(4-isopropylphenyl)-pyrazoline, 1,5-bis-(4-isopropylphenyl)-3-(4-isopropylstyryl)-pyrazoline, 1-(4-methoxyphenyl)-3-(4-tert-butyl-styryl)-5-(4-tert-butyl-phenyl)-pyrazoline, 1-(4-tert-butyl-phenyl)-3-(4-methoxystyryl)-5-(4-methoxyphenyl)-pyrazoline, 1-(4-isopropyl-phenyl)-3-(4-tert-butyl-styryl)-5-(4-tert-butyl-phenyl)-pyrazoline, 1-(4-tert-butyl-phenyl)-3-(4-isopropyl-styryl)-5-(4-isopropyl-phenyl)-pyrazoline, 1-(4-methoxyphenyl)-3-(4-isopropylstyryl)-5-(4-isopropylphenyl)-pyrazoline, 1-(4-isopropyl-phenyl)-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, 1-phenyl-3-(2,4-dimethoxystyryl)-5-(2,4-dimethoxyphenyl)-pyrazoline, 1-(4-methoxyphenyl)-3-(3,5-dimethoxystyryl)-5-(3,5-dimethoxyphenyl)-pyrazoline, 1-(4-methoxyphenyl)-3-(3,4-dimethoxystyryl)-5-(3,4-dimethoxyphenyl)-pyrazoline, 1-(4-methoxyphenyl)-3-(2,6-dimethoxystyryl)-5-(2,6-dimethoxyphenyl)-pyrazoline, 1-(4-methoxyphenyl)-3-(2,5-dimethoxystyryl)-5-(2,5-dimethoxyphenyl)-pyrazoline, 1-(4-methoxyphenyl)-3-(2,3-dimethoxystyryl)-5-(2,3-dimethoxyphenyl)-pyrazoline, 1-(4-methoxyphenyl)-3-(2,4-dimethoxystyryl)-5-(2,4-dimethoxyphenyl)-pyrazoline, 1-(4-tert-butyl-phenyl)-3-(3,5-dimethoxystyryl)-5-(3,5-dimethoxyphenyl)-pyrazoline, 1-(4-tert-butyl-phenyl)-3-(3,4-dimethoxystyryl)-5-(3,4-dimethoxyphenyl)-pyrazoline, 1-(4-tert-butyl-phenyl)-3-(2,6-dimethoxystyryl)-5-(2,6-dimethoxyphenyl)-pyrazoline, 1-(4-tert-butyl-phenyl)-3-(2,5-dimethoxystyryl)-5-(2,5-dimethoxyphenyl)-pyrazoline, 1-(4-tert-butyl-phenyl)-3-(2,3-dimethoxystyryl)-5-(2,3-dimethoxyphenyl)-pyrazoline, 1-(4-tert-butyl-phenyl)-3-(2,4-dimethoxystyryl)-5-(2,4-dimethoxyphenyl)-pyrazoline, 1-(4-isopropyl-phenyl)-3-(3,5-dimethoxystyryl)-5-(3,5-dimethoxyphenyl)-pyrazoline, 1-(4-isopropyl-phenyl)-3-(3,4-dimethoxystyryl)-5-(3,4-dimethoxyphenyl)-pyrazoline, 1-(4-isopropyl-phenyl)-3-(2,6-dimethoxystyryl)-5-(2,6-dimethoxyphenyl)-pyrazoline, 1-(4-isopropyl-phenyl)-3-(2,5-dimethoxystyryl)-5-(2,5-dimethoxyphenyl)-pyrazoline, 1-(4-isopropyl-phenyl)-3-(2,3-dimethoxystyryl)-5-(2,3-dimethoxyphenyl)-pyrazoline, and 1-(4-isopropyl-phenyl)-3-(2,4-dimethoxystyryl)-5-(2,4-dimethoxyphenyl)-pyrazoline.

Examples of the anthracene compound include 9,10-dimethoxyanthracene, 9,10-diethoxyanthracene, 9,10-dipropoxyanthracene, 9,10-dibutoxyanthracene, and 9,10-dipentoxyanthracene.

From the viewpoint of enhancing photosensitivity and resolution, the content of the component (D) may be 0.01 to 5 parts by mass, 0.01 to 1 part by mass, or 0.01 to 0.2 parts by mass, with respect to 100 parts by mass of the total amount of the component (A) and the component (B).

### (Photochromic Agent)

The photosensitive resin composition may further contain a photochromic agent as component (E), from the viewpoint of increasing the sensitivity of the photosensitive resin composition. The photochromic agent may be an amine-based compound. Examples of the photochromic agent include tribromophenylsulfone, leuco crystal violet, diphenylamine, benzylamine, triphenylamine, diethylaniline, and o-chloroaniline.

### (Other Components)

The photosensitive resin composition according to the present embodiment may further contain, if necessary, additives such as a dye, a thermochromism inhibitor, a plasticizer, a pigment, a filler, an antifoaming agent, a flame retardant, an adhesiveness imparting agent, a leveling agent, a peeling accelerator, an antioxidant, a fragrance, an imaging agent, a thermal crosslinking agent, and a polymerization inhibitor. These additives can be used singly or in combination of two or more kinds thereof.

Examples of the dye include malachite green, victoria pure blue, brilliant green, and methyl violet. Examples of the plasticizer include p-toluenesulfonamide.

The photosensitive resin composition is dissolved, if necessary, in a solvent such as methanol, ethanol, acetone, methyl ethyl ketone, methyl cellosolve, ethyl cellosolve, toluene, N,N-dimethylformamide, or propylene glycol monomethyl ether, or a mixed solvent of these and thereby can be prepared into a solution having a solid content of about 30% to 60% by mass.

### [Photosensitive Element]

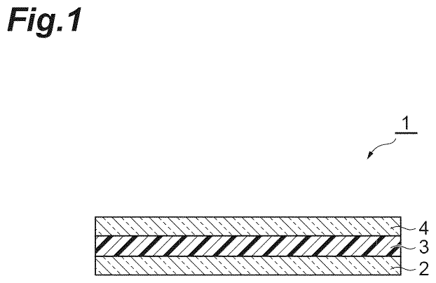

The photosensitive element according to the present embodiment comprises a support and a photosensitive layer formed on the support, and the photosensitive layer includes the above-mentioned photosensitive resin composition. When the photosensitive element of the present embodiment is used, a photosensitive layer may be laminated on a substrate and then exposed to light without peeling the support (support film). The photosensitive element 1 according to the present embodiment is configured to comprise, as shown in a schematic cross-sectional view of an example thereof in FIG. 1, a support 2 and a photosensitive layer 3 derived from the above-described photosensitive resin composition formed on the support 2 and to comprise other layers such as a protective layer 4, which are provided as needed.

Examples of the support include films of polyesters such as polyethylene terephthalate (PET), polybutylene terephthalate (PBT), and polyethylene-2,6-naphthalate (PEN); and films of polyolefins such as polypropylene and polyethylene. Among them, from the viewpoint of being easily available and having excellent handleability (particularly, heat resistance, thermal shrinkage, and breaking strength) during the production process, the support may be a PET film.

The haze of the support may be 0.01% to 1.0%, or 0.01% to 0.5%. When the haze is 0.01% or more, there is a tendency that the support itself is easily manufactured, and when the haze is 1.0% or less, there is a tendency that fine defects that may occur in the resist pattern are reduced.

The term “haze” means cloudiness. The haze according to the present disclosure refers to a value measured using a commercially available haze meter (turbidimeter) according to the method defined in JIS K 7105. The haze can be measured with, for example, a commercially available turbidimeter such as NDH-5000 (manufactured by NIPPON DENSHOKU INDUSTRIES CO., LTD.).

The thickness of the support may be 1 to 100 μm, 5 to 60 μm, 10 to 50 μm, 10 to 40 μm, 10 to 30 μm, or 10 to 25 μm. When the thickness of the support is 1 μm or more, there is a tendency that the support can be suppressed from breaking when the support is peeled off. Furthermore, when the thickness of the support is 100 μm or less, the resolution can be suppressed from being lowered in a case where exposure is performed through the support.

The photosensitive element may further comprise a protective layer as necessary. Regarding the protective layer, a film with which smaller adhesive force between the photosensitive layer and the protective layer is obtained as compared to the adhesive force between the photosensitive layer and the support, and a film with fewer fisheyes may also be used. Specifically, for example, films that can be used as the above-mentioned support may be mentioned. From the viewpoint of peelability from the photosensitive layer, the protective layer may be a polyethylene film.

The thickness of the protective layer may vary depending on the use application; however, the thickness may be 1 to 100 μm, 5 to 50 μm, 5 to 30 μm, or 15 to 30 μm. When the thickness of the protective layer is 1 μm or more, there is a tendency that the protective layer can be suppressed from breaking when the protective layer is peeled off, and when the thickness of the protective layer is 100 μm or less, inexpensiveness tends to be excellent.

The photosensitive element can be produced, for example, as follows. That is, a solution of a photosensitive resin composition (coating liquid) is applied on a support to form a coating layer, and a photosensitive layer is formed by drying this coating layer. Next, by covering a surface of the photosensitive layer, the surface being on the opposite side of the support, with a protective layer, a photosensitive element comprising a support; a photosensitive layer formed on the support; and a protective layer laminated on the photosensitive layer can be obtained.

Application of the coating liquid on the support can be carried out by, for example, any known method such as roll coating, comma coating, gravure coating, air knife coating, die coating, or bar coating.

Drying of the coating layer is not particularly limited as long as at least a portion of the organic solvent can be removed from the coating layer. For example, drying may be carried out at 70° C. to 150° C. for about 5 to 30 minutes. After drying, the amount of residual solvent may be 2% by mass or less, from the viewpoint of preventing diffusion of the solvent in subsequent steps.

The thickness of the photosensitive layer in the photosensitive element can be appropriately selected depending on the use application; however, the thickness may be 1 to 100 μm, 5 to 50 μm, or 10 to 40 μm, as the thickness after drying. When the thickness is 1 μm or more, industrial coating is facilitated, and productivity is enhanced. Furthermore, when the thickness is 100 μm or less, adhesiveness and resolution are enhanced.

Regarding the photosensitive layer, the transmittance to ultraviolet radiation at a wavelength of 365 nm is preferably 5% to 75%, more preferably 7% to 60%, and even more preferably 10% to 40%. When the transmittance is 5% or higher, adhesiveness is likely to be enhanced, and when the transmittance is 75% or lower, resolution is likely to be enhanced. The transmittance can be measured using a UV spectrometer.

The form of the photosensitive element is not particularly limited. For example, the photosensitive element may have a sheet form or may have a shape wound around a winding core into a roll form. In the case of being wound into a roll form, the photosensitive element may be wound such that the support film comes to the outer side. Examples of the winding core include plastics such as a polyethylene resin, a polypropylene resin, a polyvinyl chloride resin, or an ABS resin (acrylonitrile-butadiene-styrene copolymer).

At the end faces of the photosensitive element in a roll form, end face separators may be provided in view of protecting the end faces, and moisture-proof end face separators may be provided from the viewpoint of resistance to edge fusion. The photosensitive element may be wrapped with a black sheet having low moisture permeability and packaged.

The photosensitive element can be suitably used, for example, for a method for forming a resist pattern, which will be described below. Above all, from the viewpoint of resolution, the photosensitive element is adequate for the application to a production method for forming a conductor pattern by a plating treatment.

### [Method for Forming Resist Pattern]

The method for forming a resist pattern of the present embodiment may be configured to include: (i) a step of forming a photosensitive layer on a substrate by using the above-described photosensitive resin composition or the above-described photosensitive element (photosensitive layer forming step); (ii) a step of irradiating at least a portion (predetermined part) of the photosensitive layer to form a photocured part (exposure step); and (iii) a step of removing at least a portion of areas other than the photocured part from the substrate to form a resist pattern (developing step), and to include other steps as necessary. The resist pattern may be referred to as a photocured product pattern of the photosensitive resin composition or may be referred to as a relief pattern. The method for forming a resist pattern can be regarded as a method for producing a resist pattern-attached substrate.

### ((i) Photosensitive Layer Forming Step)

Regarding the method for forming a photosensitive layer on a substrate, for example, the above-described photosensitive resin composition may be applied and dried, or after a protective layer is removed from the photosensitive element, the photosensitive layer of the photosensitive element may be pressed against the substrate while being heated. In the case of using the photosensitive element, a laminated body comprising a substrate, a photosensitive layer, and a support, in which these are laminated in order, is obtained. The substrate is not particularly limited; however, usually, a circuit forming substrate comprising an insulation layer and a conductor layer formed on the insulation layer, or a die pad (base material for lead frame) such as an alloy base material is used.

In the case of using a photosensitive element, it is preferable that the photosensitive layer forming step is carried out under reduced pressure, from the viewpoints of adhesiveness and conformability. Heating of the photosensitive layer and/or substrate during pressing may be carried out at a temperature of 70° C. to 130° C. Pressing may be performed at a pressure of about 0.1 to 1.0 MPa (about 1 to 10 kgf/cm²); however, these conditions are appropriately selected as necessary. Incidentally, when the photosensitive layer is heated to 70° C. to 130° C., it is not necessary to preheat the substrate in advance; however, in order to further enhance adhesiveness and conformability, a preheating treatment of the substrate may be carried out.

((ii) Exposure Step)

In the exposure step, when at least a portion of the photosensitive layer formed on the substrate is irradiated with actinic light, the part irradiated with actinic light is photocured, and a latent image is formed. At this time, in a case where a support is present on the photosensitive layer, when the support is permeable to the actinic light, the photosensitive layer may be irradiated with actinic light through the support; however, in a case where the support is light-blocking, the photosensitive layer is irradiated with actinic light after the support is removed.

Regarding the exposure method, a method of irradiating the photosensitive layer imagewise with actinic light through a negative or positive mask pattern called artwork (mask exposure method) may be mentioned. Furthermore, regarding the exposure method, a method of irradiating actinic light imagewise by a projection exposure method; or a method of irradiating actinic light imagewise by a direct drawing exposure method such as an LDI (Laser Direct Imaging) exposure method or a DLP (Digital Light Processing) exposure method, may be employed.

As a light source of the actinic light, a known light source can be used, and for example, light sources that can effectively radiate ultraviolet radiation or visible rays, such as a carbon arc lamp, a mercury vapor arc lamp, a high-pressure mercury lamp, a xenon lamp, a gas laser such as an argon laser, a solid-state laser such as a YAG laser, a semiconductor laser, are used.

((iii) Developing Step)

In the developing step, a resist pattern is formed on the substrate as at least a portion of areas other than the photocured part in the photosensitive layer is removed from the substrate.

When a support is present on the photosensitive layer, removal (developing) of regions other than the photocured part (can also be referred to as unexposed parts) is performed after the support is removed. Examples of the developing method include wet developing and dry developing; however, wet developing is widely used.

In the case of adopting wet developing, developing is performed by a known developing method using a developer liquid corresponding to the photosensitive resin composition. Examples of the developing method include a dipping method, a paddle method, a spray method, and methods using brushing, slapping, scrubbing, rocking immersion, and the like, and from the viewpoint of enhancing resolution, a high-pressure spray method may be used. Developing may be performed by combining two or more methods of these.

The configuration of the developer liquid is appropriately selected according to the configuration of the photosensitive resin composition. Examples of the developer liquid include an alkaline aqueous solution and an organic solvent developer liquid.

From the viewpoint of being safe and stable and exhibiting satisfactory operability, an alkaline aqueous solution may be used as the developer liquid. Regarding the base for the alkaline aqueous solution, an alkali hydroxide such as hydroxide of lithium, sodium, or potassium; an alkali carbonate such as carbonate or bicarbonate of lithium, sodium, potassium, or ammonium; an alkali metal phosphate such as potassium phosphate or sodium phosphate; an alkali metal pyrophosphate such as sodium pyrophosphate or potassium pyrophosphate; borax, sodium metasilicate, tetramethylammonium hydroxide, ethanolamine, ethylenediamine, diethylenetriamine, 2-amino-2-hydroxymethyl-1,3-propanediol, 1,3-diaminopropanol-2, morpholine, and the like are used.

As the alkaline aqueous solution, a 0.1 mass % to 5 mass % dilute solution of sodium carbonate, a 0.1 mass % to 5 mass % dilute solution of potassium carbonate, a 0.1 mass % to 5 mass % dilute solution of sodium hydroxide, a 0.1 mass % to 5 mass % dilute solution of sodium tetraborate, or the like can be used. The pH of the alkaline aqueous solution may be in the range of 9 to 14, and the temperature can be regulated in accordance with alkali developability of the photosensitive layer. In the alkaline aqueous solution, for example, a surface active agent, an antifoaming agent, a small amount of an organic solvent for promoting developing, and the like may be incorporated.

Examples of the organic solvent used for the alkaline aqueous solution include acetone, ethyl acetate, an alkoxy ethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent used for the organic solvent developer liquid include 1,1,1-trichloroethane, N-methylpyrrolidone, N,N-dimethylformamide, cyclohexanone, methyl isobutyl ketone, and γ-butyrolactone. These organic solvents may be used as organic solvent developer liquids by adding water such that the concentration is in the range of 1% to 20% by mass, in order to prevent ignition.

With regard to the method for forming a resist pattern according to the present embodiment, after uncured parts are removed in the developing step, a step of further curing the resist pattern by heating at about 60° C. to 250° C. or performing exposure at a dose of about 0.2 to 10 J/cm² may be included as necessary.

### [Method for Forming Wiring Pattern]

The method for forming a wiring pattern according to the present embodiment has a step of subjecting the substrate having a resist pattern formed thereon by the above-described method for forming a resist pattern, to an etching treatment or a plating treatment to form a conductor pattern. The method for forming a wiring pattern may further comprise a step of removing the photocured parts using an alkaline aqueous solution, after the etching treatment or the plating treatment.

With regard to the plating treatment, the conductor layer provided on the substrate is subjected to the plating treatment by using the resist pattern formed on the substrate as a mask. After the plating treatment, the resist is removed by removal of the resist pattern that will be described below, and the conductor layer coated by this resist may be etched to form the conductor pattern. The method of the plating treatment may be an electroplating treatment or an electroless plating treatment; however, the plating treatment may be an electroless plating treatment.

In the etching treatment, the conductor layer provided on the substrate is removed by etching by using the resist pattern formed on the substrate as a mask, and a conductor pattern is formed. The method for the etching treatment is appropriately selected according to the conductor layer to be removed. Examples of the etching solution include a cupric chloride solution, a ferric chloride solution, an alkali etching solution, and a hydrogen peroxide-based etching solution.

After the etching treatment or the plating treatment, the resist pattern on the substrate may be removed. Regarding the removal of the resist pattern, for example, the resist pattern can be peeled off by means of an alkaline aqueous solution that is stronger than the alkaline aqueous solution used in the developing step. As the strong alkaline aqueous solution, for example, a 1 mass % to 10 mass % aqueous solution of sodium hydroxide or a 1 mass % to 10 mass % aqueous solution of potassium hydroxide is used. The removal of the resist pattern may be carried out at 45° C. to 65° C. using a strong alkali aqueous solution.

When the resist pattern is removed after a plating treatment is applied, the conductor layer coated with the resist is further etched by an etching treatment, a conductor pattern is formed, and thereby a desired printed wiring board can be manufactured. The method for the etching treatment at this time is appropriately selected according to the conductor layer to be removed. For example, the above-mentioned etching solution can be applied.

The method for forming a wiring pattern according to the present embodiment can be applied to the manufacture of not only a single-layer printed wiring board but also a multilayer printed wiring board and can also be applied to the manufacture of a printed wiring board having small-sized through-holes or the like.

### EXAMPLES

Hereinafter, the present disclosure will be specifically described based on Examples; however, the present disclosure is not intended to be limited to these.

### Synthesis Example 1

Butylamine (23.8 g, 0.325 mol) and dehydrated toluene (400 mL) were introduced into a flask equipped with a magnetic stirrer bar, a reflux condenser, a calcium chloride tube, a thermometer, and a dropping funnel, and the mixture was cooled to a temperature of from 0° C. to 5° C. Next, 2-isocyanatoethyl methacrylate (50.4 g, 0.325 mol) was slowly added dropwise into the flask, and then the mixture was stirred for 6 hours at room temperature to obtain a reaction liquid. A precipitate produced in the reaction liquid was collected by filtration, and a filtrate was concentrated under reduced pressure. The precipitate and the concentrate were blended to obtain a monomer U (yield 100%). The monomer U is a compound having a urea bond obtained by reacting an isocyanate group of 2-isocyanatoethyl methacrylate with an amino group of butylamine.

### [Polymer]

### Examples 1 to 4

Into a flask equipped with a stirrer, a reflux condenser, a thermometer, a dropping funnel, and a nitrogen inlet tube, styrene, benzyl methacrylate, methacrylic acid, monomer U, methyl cellosolve, and toluene were introduced in the blending amounts (g) indicated in Table 1, and while the mixture was stirred in a nitrogen atmosphere, the temperature was increased to 70° C. A mixed liquid of azobisisobutyronitrile (AIBN), methyl cellosolve, and toluene was added dropwise into the flask for 30 minutes, and then a reaction was carried out for 90 minutes at 75° C., for 2 hours at 85° C., and for 2 hours at 95° C. while the mixture was stirred. Subsequently, the reaction liquid was cooled to room temperature. Toluene in the reaction liquid was distilled off under reduced pressure, subsequently residue was introduced into water, a precipitate was collected and dried, and polymers A1 to A4 were obtained.

### Comparative Example 1

Polymer A5 was obtained in the same manner as in Examples 1 to 4, except that styrene, benzyl methacrylate, methacrylic acid, AIBN, methyl cellosolve, and toluene were used in the blending amounts (g) indicated in Table 1.

The Mw of a polymer was calculated by making measurement according to gel permeation chromatography (GPC) and converting the results using a calibration curve of polystyrene standards. The calibration curve was approximated by a cubic equation of a universal calibration curve according to JIS K 7252-2 (2016) using a set of five samples of polystyrene standards (PStQuick MP-H, PStQuick B [manufactured by Tosoh Corporation, trade name]). The conditions for GPC are shown below.

### (GPC Conditions)

Pomp and Detector: HLC-8320 (Tosoh Corporation)
Column: TSKgel SuperMultipore HZ-M (three columns) (Tosoh Corporation)
Eluent; Tetrahydrofuran (THF)
Measurement temperature: 40° C.
Flow rate: 0.35 mL/min

TABLE 1

| | Example | Example | Example | Example | Comparative |
|---|---|---|---|---|---|
| | 1 | 2 | 3 | 4 | Example 1 |
| Polymer | A1 | A2 | A3 | A4 | A5 |
| Styrene | 45 | 45 | 45 | 45 | 45 |
| Benzyl | 20 | 20 | — | — | 30 |
| methacrylate | | | | | |
| Methacrylic acid | 25 | 25 | 25 | 25 | 25 |
| Monomer U | 10 | 10 | 30 | 30 | — |
| AIBN | 1.5 | 4.0 | 1.5 | 4.0 | 1.5 |
| Methyl cellosolve | 90 | 180 | 90 | 180 | 75 |
| Toluene | 60 | 120 | 60 | 120 | 50 |
| Mw | 23000 | 10000 | 18000 | 9000 | 40000 |

### [Photosensitive Resin Composition]

A photosensitive resin composition was prepared by mixing 60 parts by mass of the polymer with various components in the blending amounts (parts by mass) indicated in Table 2.

The details of each of the components shown in Table 2 are as follows.

### (Photopolymerizable Compound)

B-1: EO-modified bisphenol A dimethacrylate (manufactured by Showa Denko Materials Co., Ltd., trade name: FA-321M)
B-2: EO-modified polypropylene glycol dimethacrylate (manufactured by Showa Denko Materials Co., Ltd., trade name: FA-023M)

### (Photopolymerization Initiator)

C-1: 2,2′-Bis(2-chlorophenyl)-4,4′,5,5′-tetraphenylbiimidazole (manufactured by Hodogaya Chemical Co., Ltd., trade name: B-CIM) (Sensitizer)
D-1: 9,10-Dibutoxyanthracene (Kawasaki Kasei Chemicals, Ltd.) (Photochromic agent)
E-1: 4,4′,4″-Methylidynetris(N,N-dimethylaniline) (Dye)
F-1: 4-[(4-Dimethylaminophenyl)-phenyl-methyl]-N,N-dimethyl-aniline

TABLE 2

| | | |
|---|---|---|
| Photopolymerizable | B-1 | 20 |
| compound | B-2 | 10 |
| Photopolymerization | C-1 | 5 |
| initiator | | |
| Sensitizer | D-1 | 1 |
| Photochromic agent | E-1 | 0.5 |
| Dye | F-1 | 0.05 |
| Solvent | Toluene | 30 |
| | 1-Methoxy- | 30 |
| | 2-propanol | |
| | Methanol | 5 |
| | Acetone | 5 |

### [Photosensitive Element]

The photosensitive resin composition was applied on a PET film having a thickness of 16 μm (Teijin Film Solution, Ltd., trade name “G2J”) (support) and dried for 2 minutes each in hot air convection dryers at 80° C. and 120° C., and thus a photosensitive layer having a thickness after drying of 35 μm was formed. A polypropylene film (Tamapoly Co., Ltd., product name “NF-13”) (protective layer) was superposed on this photosensitive layer, and a photosensitive element in which the support, the photosensitive layer, and the protective layer were laminated in this order, was obtained.

### [Evaluation]

The following evaluations were carried out using the photosensitive element. The results are shown in Table 3.

### (Stickiness)

The photosensitive element was heated to 30° C., subsequently the protective film was removed, and the presence or absence of surface stickiness of the photosensitive layer was checked.

### (Elastic Modulus)

The photosensitive layer of the photosensitive element was laminated four times at 80° C. and at a pressure of 0.4 MPa, and a photosensitive film was produced. The photosensitive film was inserted between measurement boards of a rheometer (manufactured by TA Instruments, Inc.), and the storage modulus at 30° C. and 110° C. was measured.

### (Solubility)

The photosensitive layer of the photosensitive element was laminated on a silicon substrate at 110° C. and at a pressure of 0.4 MPa and then immersed in a 1 mass % aqueous solution of sodium carbonate at 25° C., and the time required for the photosensitive layer to be completely dissolved was measured.

### (Laminated Body)

A copper clad laminated plate (manufactured by Showa Denko Materials Co., Ltd., product name: MCL-E-67) in which copper foil (thickness 35 mm) was laminated on both surfaces of a glass fiber-reinforced epoxy resin layer, was prepared. A pattern of photoresist with a ratio of line width/space width of 100 μm/100 μm was formed on one copper surface of the copper clad laminated plate, and then the copper clad laminated plate was immersed in an etching solution. Next, the photoresist was removed, and grooves having a width of 100 μm, an interval of 100 μm, and a depth of 15 μm were formed on the copper clad laminated plate.

On the surface of the copper clad laminated plate where the grooves were formed, the photosensitive element was laminated on the copper surface of the copper clad laminated plate. Lamination was carried out using a heating roll at 110° C., at a pressing pressure of 0.4 MPa and a roll speed of 1.0 m/min while the protective layer was removed. In this manner, a laminated body in which the copper clad laminated plate, the photosensitive layer, and the support were laminated in this order.

### (Conformability)

The support surface of the laminated body was irradiated with ultraviolet radiation at a dose of 10 mJ/cm² using an ultraviolet exposure machine (manufactured by Mikasa Co., Ltd., trade name: MA-20) equipped with a photomask having a rectangular pattern with a ratio of line width/space width of 100 μm/100 μm formed thereon, such that the pattern of the photomask and the direction of the grooves were perpendicular to each other. The illuminance was measured using an ultraviolet illuminance meter (manufactured by Ushio, Inc., trade name: UIT-150) to which a probe corresponding to 365 nm was applied. After the exposure, the support was peeled off, a 1 mass % aqueous solution of sodium carbonate was sprayed on the photosensitive layer at 30° C. for 90 seconds, and thus unexposed parts were removed (developing treatment).

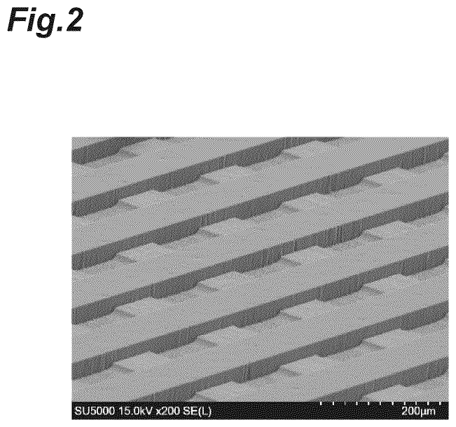

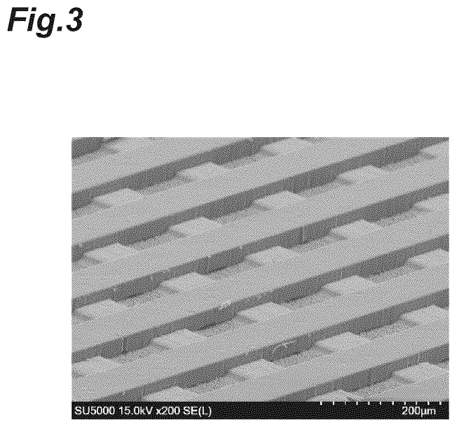

After the developing treatment, the presence or absence of gaps (voids) produced between the photosensitive layer and the grooves of the copper clad laminated plate was observed using a scanning electron microscope SU5000 manufactured by Hitachi High-Tech Corporation. FIG. 2 shows an electron microscopic photograph of the resist pattern formed in Example 5. FIG. 3 shows an electron microscopic photograph of the resist pattern formed in Comparative Example 2.

TABLE 3

| | | | | | | Comparative |
|---|---|---|---|---|---|---|
| | | Example 5 | Example 6 | Example 7 | Example 8 | Example 2 |
| Polymer | | A-1 | A-2 | A-3 | A-4 | A-5 |
| Voids | | Absent | Absent | Absent | Absent | Present |
| Stickiness | | Absent | Absent | Absent | Absent | Absent |
| Storage | 30° C. | 5 × 10⁶ | 4 × 10⁶ | 6 × 10⁶ | 5 × 10⁶ | 5 × 10⁶ |
| modulus | 110° C. | 60 | 2 | 100 | 20 | 3000 |
| (Pa) | | | | | | |

| | | | | | |
|---|---|---|---|---|---|
| Dissolution time (seconds) | 210 | 200 | 200 | 190 | 270 |

From the above-described results, it can be recognized that by using the polymers and photosensitive resin compositions of Examples, photosensitive layers that do not have layer surface stickiness at near 30° C., exhibit fluidity at 110° C., and do not have any lamination voids, can be formed.

### REFERENCE SIGNS LIST

1: Photosensitive element, 2: Support, 3: Photosensitive layer, 4: Protective layer.

1. A polymer comprising a structural unit represented by the following Formula (I) and a structural unit having a carboxy group: 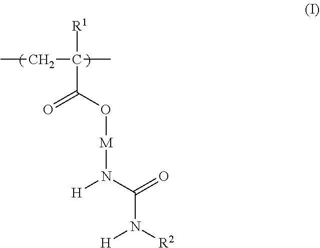
wherein in Formula (I), R¹ represents a hydrogen atom or a methyl group; M represents an alkylene group or an alkylene oxide chain; and R² represents an alkyl group or an aryl group.

2. The polymer according to claim 1, wherein the content of the structural unit represented by Formula (I) is 5% to 50% by mass based on the total amount of the polymer.

3. A photosensitive resin composition containing a binder resin including the polymer according to claim 1; a photopolymerizable compound; and a photopolymerization initiator.

4. The photosensitive resin composition according to claim 3, wherein the photopolymerization initiator includes a hexaarylbiimidazole compound.

5. The photosensitive resin composition according to claim 3 containing a sensitizer.

6. The photosensitive resin composition according to claim 3, further containing a photochromic agent.

7. A photosensitive element comprising a support film and a photosensitive layer formed on the support film,
wherein the photosensitive layer includes the photosensitive resin composition according to claim 3.

8. A method for forming a resist pattern, the method comprising:
a step of forming a photosensitive layer on a substrate by using the photosensitive resin composition according to claim 3;
a step of irradiating at least a portion of the photosensitive layer with actinic light to form a photocured part; and
a step of removing at least a portion of areas other than the photocured part in the photosensitive layer from the substrate to form a resist pattern.

9. A method for forming a wiring pattern, the method comprising a step of subjecting a substrate having a resist pattern formed thereon by the method for forming a resist pattern according to claim 8 to an etching treatment or a plating treatment to form a conductor pattern.

10. The method for forming a wiring pattern according to claim 9, further comprising, after the etching treatment or the plating treatment, a step of removing the photocured part using an alkaline aqueous solution.

11. A method for forming a resist pattern, the method comprising:
a step of forming a photosensitive layer on a substrate by using the photosensitive element according to claim 7;
a step of irradiating at least a portion of the photosensitive layer with actinic light to form a photocured part; and
a step of removing at least a portion of areas other than the photocured part in the photosensitive layer from the substrate to form a resist pattern.

12. A method for forming a wiring pattern, the method comprising a step of subjecting a substrate having a resist pattern formed thereon by the method for forming a resist pattern according to claim 11 to an etching treatment or a plating treatment to form a conductor pattern.

13. The method for forming a wiring pattern according to claim 12, further comprising, after the etching treatment or the plating treatment, a step of removing the photocured part using an alkaline aqueous solution.
